(19) United States
(12) Patent Application Publication
(10) Pub. No.: US 2024/0429108 A1
(43) Pub. Date: Dec. 26, 2024

(54) JOINED BODY, METHOD OF MANUFACTURING JOINED BODY, AND METHOD OF EVALUATING ORGANIC RESIDUES OF JOINED BODY

(71) Applicant: MITSUBISHI MATERIALS CORPORATION, Tokyo (JP)

(72) Inventors: Shujie Fei, Sanda-shi (JP); Tsukasa Yasoshima, Sanda-shi (JP); Kazuki Hirose, Sanda-shi (JP)

(73) Assignee: MITSUBISHI MATERIALS CORPORATION, Tokyo (JP)

(21) Appl. No.: 18/689,879

(22) PCT Filed: Sep. 2, 2022
(86) PCT No.: PCT/JP2022/033100

§ 371 Date: Mar. 7, 2024

(30) Foreign Application Priority Data
Sep. 9, 2021 (JP) 2021-146645

(51) Int. Cl. H01L 21/66; B23K 1/00; B23K 35/02; B23K 35/26; B23K 35/30; B23K 101/40; C22C 5/02; C22C 13/00; H01L 23/00

(52) U.S. Cl. CPC H01L 22/12; B23K 1/0016; B23K 35/0244; B23K 35/262; B23K 35/3013; C22C 5/02; C22C 13/00; H01L 24/32; H01L 24/83; B23K 2101/40; H01L 2224/32225; H01L 2224/83801

(57) ABSTRACT

What is provided is a joined body in which a first member and a second member are joined through a solder layer therebetween, in which the joined body is dipped in isopropanol to extract organic residues contained in the joined body, a UV absorption spectrum of an extract having the extracted organic residues is measured, the obtained UV absorption spectrum is normalized with the absorbance set to 100 at a wavelength of 207 nm, and the absorbance at a wavelength of 300 nm obtained from the normalized UV absorption spectrum is 4 or less.

### TECHNICAL FIELD

The present invention relates to a joined body in which a first member and a second member are joined through a solder layer therebetween, a method of manufacturing the joined body, and a method of evaluating organic residues of the joined body.

Priority is claimed on Japanese Patent Application No. 2021-146645, filed Sep. 9, 2021, the content of which is incorporated herein by reference.

### BACKGROUND ART

For example, various devices such as LEDs and power modules have a structure in which an electronic component such as a semiconductor element is joined on a circuit layer made from a metal part.

Here, in a case where an electronic component such as a semiconductor element is joined on a circuit layer, a method using a solder material is widely used, for example, as disclosed in Patent Documents 1 and 2. Recently, from the viewpoint of environmental protection, for example, lead-free solder such as Sn—Ag-based, Sn—In-based, or Sn—Ag—Cu-based solder has been the mainstream.

### CITATION LIST

### Patent Documents

### [Patent Document 1]

Japanese Unexamined Patent Application, First Publication No. 2011-083809

### [Patent Document 2]

Japanese Patent No. 6566095

### SUMMARY OF INVENTION

### Technical Problem

As described in Patent Documents 1 and 2, in various devices (joined bodies) in which an electronic component such as a semiconductor element and a circuit layer are joined through a solder material therebetween, residues of organic components (organic residues) contained in the solder material are present in the solder layer. Thus, there is a concern that a problem such as a decrease in brazing bonding strength may occur. In addition, there is a concern that the organic residues may adversely affect a substrate surface and various devices such as LEDs and power modules. In a subsequent step such as wire bonding, there is a concern that organic residues may interfere with the bonding between the wires and the substrate surface and the brazing bonding strength may be decreased.

Here, examples of the method of evaluating organic residues include a method of measuring organic matter by a TG-DTA method and a method of estimating the amount of organic matter by measuring the electrical conductivity of a cleaning liquid that has been used for cleaning of a joined body.

However, the TG-DTA method does not have sufficient accuracy, and with this, minute amounts of organic residues cannot be evaluated. In addition, with the method of measuring the electrical conductivity of a cleaning liquid that has been used for cleaning of a joined body, an organic component having weak ionicity cannot be evaluated.

Therefore, it is not possible to accurately evaluate organic residues in a joined body produced by bonding through a solder layer, and it is difficult to provide a joined body in which organic residues are reliably reduced.

The present invention has been made in view of the above-described circumstances, and an objective thereof is to provide a joined body produced by bonding through a solder layer, in which organic residues are sufficiently and reliably reduced and it is possible to suppress the occurrence of a problem such as a decrease in brazing bonding strength caused by the organic residues, a method of manufacturing the joined body, and a method of evaluating the organic residues of the joined body, in which it is possible to accurately evaluate an organic residue amount.

### Solution to Problem

In order to solve the problems, a joined body according to the present invention is a joined body in which a first member and a second member are joined through a solder layer therebetween, in which the joined body is dipped in isopropanol to extract organic residues contained in the joined body, a UV absorption spectrum of an extract having the extracted organic residues is measured, the obtained UV absorption spectrum is normalized with an absorbance set to 100 at a wavelength of 207 nm, and an absorbance at a wavelength of 300 nm obtained from the normalized UV absorption spectrum is 4 or less.

According to the joined body according to the present invention, the joined body is dipped in isopropanol to extract organic residues contained in the joined body, and the UV absorption spectrum of an extract having the extracted organic residues is measured. Accordingly, the amount of the organic residues contained in the joined body can be evaluated with high accuracy.

The obtained UV absorption spectrum is normalized with an absorbance set to 100 at a wavelength of 207 nm, and the absorbance at a wavelength of 300 nm obtained from the normalized UV absorption spectrum is limited to 4 or less. Therefore, the amount of the organic residues contained in the joined body is sufficiently reduced, and it is possible to suppress the occurrence of problems such as a decrease in brazing bonding strength caused by the organic residues.

A method of manufacturing a joined body according to the present invention is a method of manufacturing a joined body in which a first member and a second member are joined through a solder layer therebetween, including: a laminating step of laminating the first member and the second member through the solder material therebetween; a bonding step of heating and solder-bonding the first member and the second member laminated through the solder material therebetween; an ultrasonic cleaning step of subjecting the first member and the second member joined together to ultrasonic cleaning; and an ultraviolet irradiation step of applying ultraviolet rays after the ultrasonic cleaning step, in which the joined body is dipped in isopropanol to extract organic residues contained in the joined body, a UV absorption spectrum of an extract having the extracted organic residues is measured, the obtained UV absorption spectrum is normalized with an absorbance set to 100 at a wavelength of 207 nm, and an absorbance at a wavelength of 300 nm obtained from the normalized UV absorption spectrum is adjusted to 4 or less.

According to the method of manufacturing a joined body according to the present invention, the ultrasonic cleaning step of subjecting the first member and the second member joined together to ultrasonic cleaning and the ultraviolet irradiation step of applying ultraviolet rays after the ultrasonic cleaning step are provided. Therefore, the organic residues of the joined body can be sufficiently reduced.

In addition, the joined body can be dipped in isopropanol to extract organic residues contained in the joined body, a UV absorption spectrum of an extract having the extracted organic residues can be measured, the obtained UV absorption spectrum can be normalized with an absorbance set to 100 at a wavelength of 207 nm, and an absorbance at a wavelength of 300 nm obtained from the normalized UV absorption spectrum can be adjusted to 4 or less. It is possible to manufacture a joined body in which it is possible to suppress the occurrence of a problem such as a decrease in brazing bonding strength caused by the organic residues.

A method of evaluating organic residues of a joined body according to the present invention is a method of evaluating organic residues of a joined body in which a first member and a second member are joined through a solder layer therebetween, including: an extraction step of dipping the joined body in isopropanol to extract the organic residues of the joined body; a UV absorption spectrum measurement step of measuring a UV absorption spectrum of an extract having the extracted organic residues; a normalization step of normalizing the obtained UV absorption spectrum with an absorbance set to 100 at a wavelength of 207 nm; an absorbance calculation step of calculating an absorbance at a wavelength of 300 nm from the normalized UV absorption spectrum; and an evaluation step of evaluating an organic residue amount of the joined body from the calculated absorbance.

According to the method of evaluating organic residues of a joined body according to the present invention, the joined body is dipped in isopropanol to extract organic residues contained in the joined body, a UV absorption spectrum of an extract having the extracted organic residues is measured, the obtained UV absorption spectrum is normalized with an absorbance set to 100 at a wavelength of 207 nm, an absorbance at a wavelength of 300 nm obtained from the normalized UV absorption spectrum is calculated, and an organic residue amount of the joined body is evaluated from the absorbance at a wavelength of 300 nm. Therefore, the amount of the organic residues contained in the joined body can be evaluated with high accuracy.

### ADVANTAGEOUS EFFECTS OF INVENTION

According to the present invention, organic residues are sufficiently and reliably reduced in a joined body produced by bonding through a solder layer. It is possible to provide a joined body in which it is possible to suppress the occurrence of a problem such as a decrease in brazing bonding strength caused by organic residues, a method of manufacturing the joined body, and a method of evaluating the organic residues of the joined body, in which it is possible to accurately evaluate an organic residue amount.

### BRIEF DESCRIPTION OF DRAWINGS

FIG. 1 is an explanatory diagram of a joined body according to one embodiment of the present invention.

FIG. 2 is a flowchart of a method of evaluating organic residues of a joined body according to one embodiment of the present invention.

FIG. 3 is a flowchart of a method of manufacturing a joined body according to one embodiment of the present invention.

FIG. 4 is an explanatory diagram of a method of manufacturing a joined body according to one embodiment of the present invention.

FIG. 5 is an explanatory diagram of a wire shear evaluation in examples.

### DESCRIPTION OF EMBODIMENTS

Hereinafter, a joined body, a method of manufacturing the joined body, and a method of evaluating organic residues of the joined body according to an embodiment of the present invention will be described with reference to the drawings.

As shown in FIG. 1, a joined body 10 according to the present embodiment is produced by bonding a first member 11 and a second member 12 through a solder layer 13 therebetween. In the present embodiment, the joined body 10 is a semiconductor device in which a circuit layer (first member 11) of an insulating circuit substrate and a semiconductor element (second member 12) are joined through a solder layer 13 therebetween.

Here, the circuit layer (first member 11) is formed of, for example, a highly conductive metal such as copper or a copper alloy, aluminum or an aluminum alloy, or iron or an iron alloy, and in the present embodiment, the circuit layer is formed of an iron alloy (kovar). A noble metal film such as Au is preferably formed on a bonding surface of the circuit layer (first member 11).

Further, a noble metal film such as Au is preferably formed on a bonding surface of the semiconductor element (second member 12).

The solder material constituting the solder layer 13 is appropriately selected according to the materials of the bonding surfaces of the first member 11 and the second member 12 to be joined.

In the present embodiment, in a case where the bonding surface of the circuit layer (first member 11) and the bonding surface of the semiconductor element (second member 12) are formed of a noble metal (Au), for example, Sn—Ag—Cu-based solder, Au—Sn-based solder, Sn—Cu-based solder, or the like can be applied as the solder material. In the present embodiment, the solder material constituting the solder layer 13 is Au—Sn solder having an Sn content of 10 mass % or more and 80 mass % or less and a balance consisting of Au and inevitable impurities.

Regarding the joined body 10 according to the present embodiment, the joined body 10 is dipped in isopropanol to obtain an extract having organic residues of the joined body 10 extracted therein, the UV absorption spectrum of the extract is measured, the obtained UV absorption spectrum is normalized with an absorbance set to 100 at a wavelength of 207 nm, and the absorbance at a wavelength of 300 nm obtained from the normalized UV absorption spectrum is 4 or less.

As described above, in the joined body 10 according to the present embodiment, the organic residues are evaluated by measuring the UV absorption spectrum of the extract obtained by dipping in isopropanol.

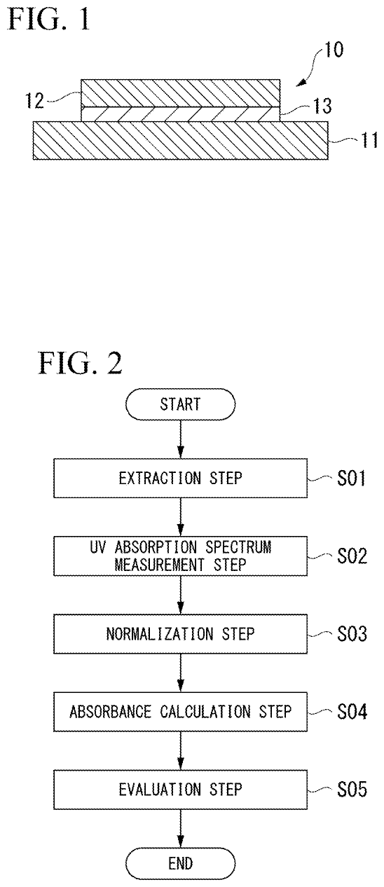

Here, a method of evaluating the organic residues of the joined body according to the present embodiment will be described with reference to FIG. 2.

### Extraction Step S01

The above-described joined body 10 is dipped in isopropanol with a purity of 99.99 vol % to extract organic residues contained in the joined body 10 into the isopropanol, and an extract having the extracted organic residues is obtained. The dipping time in the extraction step S01 is preferably within a range of 10 minutes or longer and 60 minutes or shorter. In addition, in the extraction step S01, the dipped joined body 10 and the isopropanol are preferably irradiated with ultrasonic waves.

### UV Absorption Spectrum Measurement Step S02

Next, the UV absorption spectrum of the obtained extract is measured to obtain the UV absorption spectrum of the extract. As a method of obtaining the UV absorption spectrum, it is possible to use a general spectrophotometer and a UV absorption spectrum detector of an HPLC device.

Further, the UV absorption spectrum of isopropanol with a purity of 99.99 vol % that has not been subjected to the extraction of organic residues (hereinafter, referred to as the base liquid) is also measured in the same manner as in the case of the extract to obtain the UV absorption spectrum of the base liquid.

### Normalization Step S03

Next, in the UV absorption spectrum of the extract, the absorbance at a wavelength of 207 nm is set to 100 and the absorbance at each wavelength of the UV absorption spectrum is normalized.

Similarly, in the UV absorption spectrum of the base liquid, the absorbance at a wavelength of 207 nm is set to 100 and the absorbance at each wavelength of the UV absorption spectrum is normalized.

### Absorbance Calculation Step S04

Next, a difference between the normalized absorbance of the extract at a wavelength of 300 nm and the normalized absorbance of the base liquid at a wavelength of 300 nm is obtained, and the difference is defined as “absorbance at a wavelength of 300 nm (normalized absorbance)”.

### Evaluation Step S05

Next, the organic residues of the joined body 10 are evaluated from the calculated “absorbance at a wavelength of 300 nm”.

In the present embodiment, in a case where the “absorbance at a wavelength of 300 nm” is 4 or less, the organic residues are evaluated to be sufficiently reduced.

By evaluating the organic residues of the joined body 10 as described above, it is possible to accurately evaluate the amount of the organic residues in and around the joined body 10.

In addition, by adjusting the “absorbance at a wavelength of 300 nm” to 4 or less, the organic residues in and around the solder layer 13 are sufficiently reduced, and thus it is possible to improve the brazing bonding strength between the first member 11 and the second member 12.

The “absorbance at a wavelength of 300 nm” in the joined body 10 is preferably 4 or less, and more preferably 1 or less.

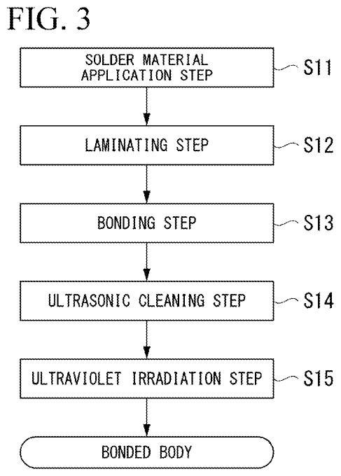

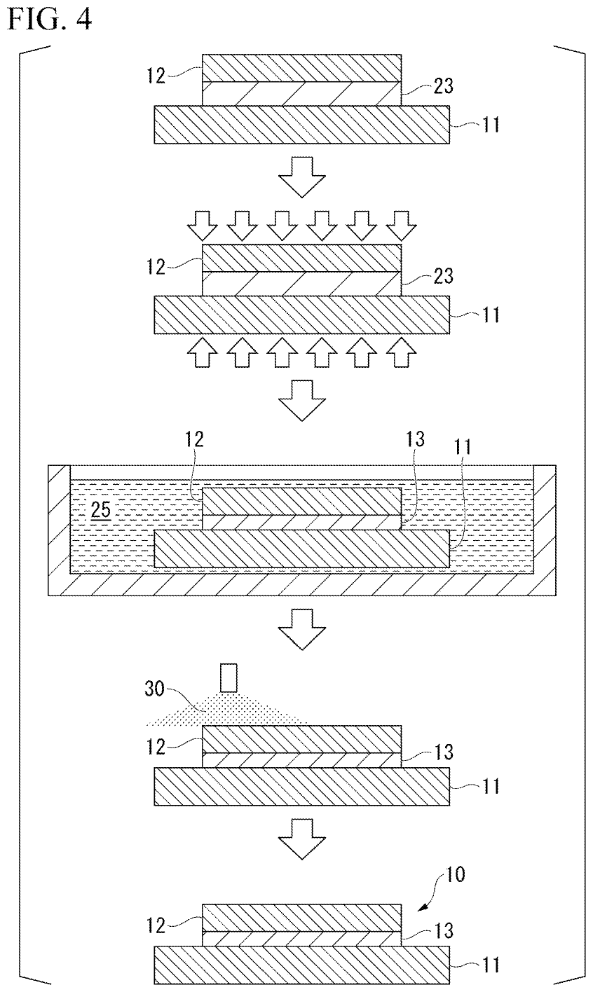

Next, a method of manufacturing the joined body 10 according to the present embodiment will be described with reference to FIGS. 3 and 4.

### Solder Material Application Step S11

As shown in FIG. 4, a solder material 23 is applied to one or both of the bonding surface of the first member 11 and the bonding surface of the second member 12. The application method is not particularly limited, and for example, a metal mask method, a screen-printing method, a dispensing method, or the like can be applied.

The solder material 23 contains a metal powder and a flux (solvent, thixotropic agent, activator, resin).

The metal powder is the above-described Sn—Ag—Cu, Au—Sn, or Sn—Cu, and these may be alloy powders or mixed powders. In the present embodiment, a mixed powder of an Au powder and a Sn powder is used.

As the solvent included in the flux, for example, alcohols, ketones, esters, ethers, aromatic solvents, hydrocarbons, terpene-based solvents, terpenoid-based solvents, and the like can be used. Specifically, benzyl alcohol, ethanol, ethyl alcohol, isopropyl alcohol, butanol, diethylene glycol, ethylene glycol, ethyl cellosolve, butyl cellosolve, butyl carbitol, isopropyl alcohol, ethyl acetate, butyl acetate, butyl benzoate, diethyl adipate, dodecane, tetradecene, α-terpineol, 2-methyl-2,4-pentanediol, 2-ethyl-1,3-hexanediol, toluene, xylene, propylene glycol monophenyl ether, diethylene glycol monohexyl ether, ethylene glycol monobutyl ether, diethylene glycol monobutyl ether, diisobutyl adipate, hexylene glycol, cyclohexanedimethanol, 2-terpinyloxyethanol, 2-dihydroterpinyloxyethanol, citral, linalool, limonene, carvacrol, pinene, farnesene, and the like are used alone or as a mixture thereof.

As the thixotropic agent, for example, a hardened castor oil, a hydrogenated castor oil, carnauba wax, amides, hydroxy fatty acids, dibenzylidene sorbitol, bis(p-methylbenzylidene) sorbitols, beeswax, stearic acid amide, hydroxystearic acid ethylenebisamide, and the like are used alone or as a mixture thereof.

As the activator, for example, fatty acids such as an adipic acid, a caprylic acid, a lauric acid, a myristic acid, a palmitic acid, a stearic acid, and a behenic acid, hydroxy fatty acids such as a 1,2-hydroxystearic acid, antioxidants, surfactants, amines, and the like are added and used.

As the resin, for example, polymerized rosin, natural rosin, purified rosin, and the like are used.

### Laminating Step S12

Next, as shown in FIG. 4, the first member 11 and the second member 12 are laminated through the above-described solder material 23 therebetween.

### Bonding Step S13

Next, as shown in FIG. 4, the first member 11 and the second member 12 laminated through the solder material 23 therebetween are heated to form the solder layer 13, and the first member 11 and the second member 12 are joined together.

Here, during the heat treatment, the organic component of the flux contained in the solder material 23 is decomposed and a gas is generated.

The heating temperature in the bonding step S13 is not particularly limited and preferably within a range of 200° C. or higher and 300° C. or lower. Furthermore, during the heat treatment, the laminate may be pressurized in the lamination direction with a pressure of 0 MPa or more and 0.0007 MPa or less.

### Ultrasonic Cleaning Step S14

Next, as shown in FIG. 4, the first member 11 and the second member 12 joined through the solder layer 13 therebetween are dipped in a cleaning solvent 25 and ultrasonic waves are applied thereto to subject the joined body 10 to ultrasonic cleaning.

Here, as the cleaning solvent 25, hot water (temperature: 50° C. or higher and 80° C. or lower), a PINE ALPHA solution, and the like are preferably used.

In addition, the ultrasonic wave application time is preferably within a range of 10 minutes or longer and 60 minutes or shorter.

### Ultraviolet Irradiation Step S15

Next, drying is performed after the ultrasonic cleaning, and then for the first member 11 and the second member 12 joined through the solder layer 13 therebetween, application of ultraviolet rays 30 to the surface of the entire joined body 10 is performed on the entire joined body 10 including the solder layer 13. The wavelength of the ultraviolet rays 30 is preferably 160 nm or more and 175 nm or less, and the illuminance is preferably 100 mW/cm² or more and 150 mW/cm² or less.

Through the ultrasonic cleaning step S14 and the ultraviolet irradiation step S15 described above, the organic residues of the joined body 10 are reduced and the “absorbance at a wavelength of 300 nm” in the joined body 10 is adjusted to 4 or less. The irradiation time for the ultraviolet rays 30 is preferably within a range of 5minutes or longer and 60 minutes or shorter.

Through the solder material application step S11, the laminating step S12, the bonding step S13, the ultrasonic cleaning step S14, and the ultraviolet irradiation step S15 described above, the joined body 10 according to the present embodiment is manufactured.

According to the joined body 10 according to the present embodiment configured as described above, the joined body 10 is dipped in isopropanol to extract organic residues contained in the joined body 10, and the UV absorption spectrum of an extract having the extracted organic residues is measured. Accordingly, the amount of the organic residues contained in the joined body 10 can be evaluated with high accuracy.

The obtained UV absorption spectrum is normalized with an absorbance set to 100 at a wavelength of 207 nm, and the absorbance at a wavelength of 300 nm obtained from the normalized UV absorption spectrum is limited to 4 or less. Therefore, the amount of the organic residues contained in the joined body 10 is sufficiently reduced, and it is possible to suppress the occurrence of a problem such as a decrease in brazing bonding strength caused by the organic residues.

In addition, according to the method of manufacturing the joined body 10 according to the present embodiment, the ultrasonic cleaning step S14 of subjecting the first member 11 and the second member 12 joined through the solder layer 13 therebetween to ultrasonic cleaning and the ultraviolet irradiation step S15 of irradiating the first member 11 and the second member 12 joined through the solder layer 13 therebetween with ultraviolet rays 30 after the ultrasonic cleaning step S14 are provided. Therefore, the organic residues of the joined body 10 can be sufficiently reduced.

Accordingly, the absorbance of the joined body 10 at a wavelength of 300 nm can be adjusted to 4 or less, and it is possible to manufacture a joined body 10 in which it is possible to suppress the occurrence of a problem such as a decrease in brazing bonding strength caused by the organic residues.

In addition, according to the method of evaluating the organic residues of the joined body 10 according to the present embodiment, as shown in FIG. 2, the extraction step S01 of dipping the joined body 10 in isopropanol to extract organic residues of the joined body, the UV absorption spectrum measurement step S02 of measuring the UV absorption spectrum of an extract having the extracted organic residues, the normalization step S03 of normalizing the obtained UV absorption spectrum with an absorbance set to 100 at a wavelength of 207 nm, the absorbance calculation step S04 of calculating an absorbance at a wavelength of 300 nm from the normalized UV absorption spectrum, and the evaluation step S05 of evaluating an organic residue amount of the joined body from the calculated absorbance at a wavelength of 300 nm are provided. Therefore, the amount of the organic residues contained in the joined body 10 can be evaluated with high accuracy.

The embodiments of the present invention have been described as above, but the present invention is not limited thereto, and can be appropriately changed without departing from the technical ideas of the present invention.

### EXAMPLES

Results of a verification experiment conducted to verify the effectiveness of the present invention will be described below.

As a first member, a substrate having a Ni plating (thickness: 0.5 to 1.0 μm) formed as a base layer on a surface of an iron alloy (kovar) plate (250 mm×150 mm×thickness 0.1 mm), and having an Au plating (thickness: 0.05 μm) formed on the Ni plating was prepared.

As a second member, a dummy chip (1 mm×1 mm×thickness 0.04 mm) having a bonding surface subjected to Au plating (thickness: 0.05 μm) was prepared.

In addition, a solder material containing a metal powder and a flux shown in Table 1 was prepared. As the flux, a flux containing 52 mass % of diethylene glycol monohexyl ether as a solvent, 5 mass % of a hardened castor oil as a thixotropic agent, 3 mass % of an adipic acid as a thixotropic agent, and 40 mass % of polymerized rosin as a resin was used.

The above-described solder material was applied to a bonding surface of the first member to form an application thickness of 200 μm, and the second member was laminated through the solder material therebetween. The laminate was heated in a nitrogen atmosphere under conditions shown in Table 1, and the first member and the second member were joined through a solder layer therebetween.

After bonding, ultrasonic cleaning was performed under conditions shown in Table 1 in Invention Examples 1 to 5 and Comparative Example 1. In Comparative Examples 2 and 3, ultrasonic cleaning was not performed.

Further, for Invention Examples 1 to 5 and Comparative Examples 1 to 3,ultraviolet irradiation was performed under conditions shown in Table 1. Here, ultraviolet rays having a wavelength of 172 nm and an illuminance of 140 mW/cm² were applied to the entire joined body.

With the joined body obtained as described above, calculation of an absorbance and a wire shear evaluation were performed as follows.

### Absorbance

The obtained joined body was put in a screw bottle (capacity: 50 mL) and 2 mL of isopropanol (purity: 99.99 vol %) was put in the screw bottle. Ultrasonic waves were applied for 5 minutes (device: manufactured by SHARP CORPORATION, model number: UC-6200, ultrasonic intensity setting: 5th stage in 5-stage setting of the device) and organic residues contained in the joined body were extracted (dipping time in isopropanol: total of 7 minutes). Thereafter, the joined body was taken out to obtain an extract.

5 μL of the extract was injected without mounting a column on an HPLC device (general-purpose HPLC Prominence manufactured by Shimadzu Corporation), and the UV absorption spectrum of the extract was measured using a UV absorption spectrum detector (SPD-20) attached to the HPLC device. The mobile phase was isopropanol and the flow rate was 0.1 mL/min (3 min)→1.0 mL/min (5 min).

The UV absorption spectrum of isopropanol with a purity of 99.99 vol % that had not been subjected to the extraction of organic residues was also measured in the same manner to measure the UV absorption spectrum of the base liquid.

In the UV absorption spectrum of the extract, the absorbance at a wavelength of 207 nm was set to 100 and the absorbance at each wavelength of the UV absorption spectrum was normalized. Similarly, in the UV absorption spectrum of the base liquid, the absorbance at a wavelength of 207 nm was set to 100 and the absorbance at each wavelength of the UV absorption spectrum was normalized.

Then, in the normalized absorbance at a wavelength of 300 nm, a difference between the absorbance of the extract and the absorbance of the base liquid was obtained and recorded as “Absorbance” in Table 1.

### Wire Shear Evaluation

Gold wire bonding was performed on a dummy chip surface and a substrate surface (the surface of the first member) of the obtained joined body. A bonding place on the substrate surface (the surface of the first member) was 500 μm away from an end of the bonding part between the dummy chip and the substrate toward a side opposite to the dummy chip.

A gold wire having a purity of 99.99 mass % and a diameter of 25 μm was used. As bonding conditions, the bonding temperature was set to 250° C., the pressing force was set to 0.6 N, and output conditions of an electric torch for a ball diameter of 50 μm were set. The ultrasonic application time was 10 ms.

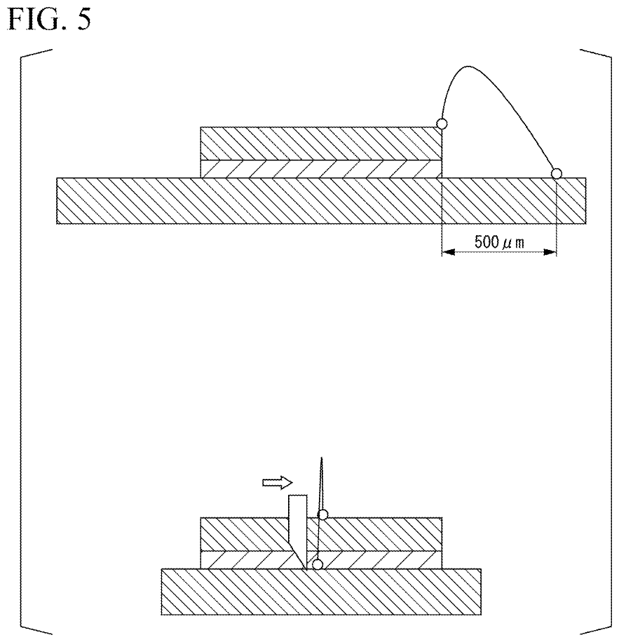

Then, the brazing bonding strength of the wire was evaluated by a shear test. As shown in FIG. 5, a lateral force was applied to a wire ball for breaking. A case where the force when the wire ball and the bonding part of the substrate were broken was larger than 170 mN was evaluated as “A”, a case where the above force was larger than 150 mN and 170 mN or less was evaluated as “B”, and a case where the above force was 150 mN or less was evaluated as “C”.

TABLE 1

| | | | | | | Ultrasonic | Ultraviolet | | |
|---|---|---|---|---|---|---|---|---|---|
| | | Solder Material | | Bonding Conditions | | Cleaning | Irradiation | | |
| | | Composition | Flux | Heating | Holding | Cleaning | Irradiation | | |
| | | of Metal | Proportion | Temperature | Time | Time | Time | | Wire Shear |
| | | Powder | (mass %) | (° C.) | (min) | (min) | (min) | Absorbance | Evaluation |
| Invention | 1 | Sn—3.0%Ag—0.5%Cu | 13 | 240 | 0.5 | 5 | 5 | 0.5 | A |
| Examples | 2 | Au—22%Sn | 10 | 300 | 0.5 | 5 | 5 | 0.5 | A |
| | 3 | Au—20%Sn | 6 | 300 | 0.5 | 5 | 5 | 0.5 | A |
| | 4 | Sn—0.7%Cu | 18 | 245 | 0.5 | 5 | 5 | 0.9 | A |
| | 5 | Sn—0.7%Cu | 18 | 245 | 0.5 | 5 | 1 | 3.8 | B |
| Comparative | 1 | Sn—3.0%Ag—0.5%Cu | 13 | 240 | 0.5 | 5 | 1 | 5.0 | C |
| Examples | 2 | Au—22%Sn | 10 | 300 | 0.5 | None | 5 | 12.0 | C |
| | 3 | Sn—0.7%Cu | 18 | 245 | 0.5 | None | 5 | 15.0 | C |

In Comparative Example 1, the bonding was performed using Sn—Ag—Cu-based solder, and the ultrasonic cleaning and the ultraviolet irradiation were performed. However, the “absorbance at a wavelength of 300 nm” was 5.0 and the result of the wire shear evaluation was “C”. The reason for this is presumed to be that the organic residues were not sufficiently reduced and the brazing bonding strength of the wire was insufficient due to the influence of the organic residues.

In Comparative Example 2, the bonding was performed using Au—Sn-based solder. In addition, the ultrasonic cleaning was not performed, but the ultraviolet irradiation was performed. The “absorbance at a wavelength of 300 nm” was 12.0 and the result of the wire shear evaluation was “C”. The reason for this is presumed to be that the organic residues were not sufficiently reduced and the brazing bonding strength of the wire was insufficient due to the influence of the organic residues.

In Comparative Example 3, the bonding was performed using Sn—Cu-based solder. In addition, the ultrasonic cleaning was not performed, but the ultraviolet irradiation was performed. The “absorbance at a wavelength of 300 nm” was 15.0 and the result of the wire shear evaluation was “C”. The reason for this is presumed to be that the organic residues were not sufficiently reduced and the brazing bonding strength of the wire was insufficient due to the influence of the organic residues.

On the other hand, In Invention Example 1, the bonding was performed using Sn—Ag—Cu-based solder, and the ultrasonic cleaning and the ultraviolet irradiation were performed. As a result, the “absorbance at a wavelength of 300 nm” was 0.5 and the result of the wire shear evaluation was “A”.

In Invention Examples 2 and 3, the bonding was performed using Au—Sn-based solder, and the ultrasonic cleaning and the ultraviolet irradiation were performed. As a result, the “absorbance at a wavelength of 300 nm” was 0.5 and the result of the wire shear evaluation was “A” in both of the examples.

In Invention Example 4, the bonding was performed using Sn—Cu-based solder, and the ultrasonic cleaning and the ultraviolet irradiation were performed. As a result, the “absorbance at a wavelength of 300 nm” was 0.9 and the result of the wire shear evaluation was “A”.

In Invention Example 5, the bonding was performed using Sn—Cu-based solder, and the ultrasonic cleaning and the ultraviolet irradiation were performed. As a result, the “absorbance at a wavelength of 300 nm” was 3.8 and the result of the wire shear evaluation was “B”.

From the results of the verification experiment, it has been confirmed that according to the invention examples, it is possible to provide a joined body produced by bonding through a solder layer, in which organic residues are sufficiently and reliably reduced and it is possible to suppress the occurrence of a problem such as a decrease in brazing bonding strength caused by the organic residues, a method of manufacturing the joined body, and a method of evaluating the organic residues of the joined body, in which it is possible to accurately evaluate an organic residue amount.

### INDUSTRIAL APPLICABILITY

According to the present invention, organic residues are sufficiently and reliably reduced in a joined body produced by bonding through a solder layer. It is possible to provide a joined body in which it is possible to suppress the occurrence of a problem such as a decrease in brazing bonding strength caused by organic residues, a method of manufacturing the joined body, and a method of evaluating the organic residues of the joined body, in which it is possible to accurately evaluate the organic residue amount. Therefore, the present invention is industrially applicable.

### REFERENCE SIGNS LIST

10: Joined body
11: First member
12: Second member
13: Solder layer
23: Solder material
30: Ultraviolet rays

1. A joined body in which a first member and a second member are joined through a solder layer therebetween,
wherein the joined body is dipped in isopropanol to extract organic residues contained in the joined body, a UV absorption spectrum of an extract having the extracted organic residues is measured, the obtained UV absorption spectrum is normalized with an absorbance set to 100 at a wavelength of 207 nm, and an absorbance at a wavelength of 300 nm obtained from the normalized UV absorption spectrum is 4 or less.

2. A method of manufacturing a joined body in which a first member and a second member are joined through a solder layer therebetween, the method comprising:
a laminating step of laminating the first member and the second member through the solder material therebetween;
a bonding step of heating and solder-bonding the first member and the second member laminated through the solder material therebetween;
an ultrasonic cleaning step of subjecting the first member and the second member joined together to ultrasonic cleaning; and
an ultraviolet irradiation step of applying ultraviolet rays after the ultrasonic cleaning step,
wherein the joined body is dipped in isopropanol to extract organic residues contained in the joined body, a UV absorption spectrum of an extract having the extracted organic residues is measured, the obtained UV absorption spectrum is normalized with an absorbance set to 100 at a wavelength of 207 nm, and an absorbance at a wavelength of 300 nm obtained from the normalized UV absorption spectrum is adjusted to 4 or less.

3. A method of evaluating organic residues of a joined body in which a first member and a second member are joined through a solder layer therebetween, the method comprising:
an extraction step of dipping the joined body in isopropanol to extract the organic residues of the joined body;
a UV absorption spectrum measurement step of measuring a UV absorption spectrum of an extract having the extracted organic residues;
a normalization step of normalizing the obtained UV absorption spectrum with an absorbance set to 100 at a wavelength of 207 nm;
an absorbance calculation step of calculating an absorbance at a wavelength of 300 nm from the normalized UV absorption spectrum; and
an evaluation step of evaluating an organic residue amount of the joined body from the calculated absorbance.
